(19) United States
(12) Patent Application Publication
(10) Pub. No.: US 2013/0001647 A1
(43) Pub. Date: Jan. 3, 2013

(54) INTEGRATION OF VERTICAL BJT OR HBT INTO SOI TECHNOLOGY

(76) Inventor: Steven J. Adler, Saratoga, CA (US)

(21) Appl. No.: 13/170,473

(22) Filed: Jun. 28, 2011

(51) Int. Cl. H01L 21/331; H01L 29/737; H01L 29/732

(52) U.S. Cl. 257/197; 438/311; 257/586; 257/E21.371; 257/E21.375; 257/E29.185; 257/E29.189

(57) ABSTRACT

In an embodiment, a bipolar transistor structure is formed on a silicon-on-insulator (SOI) structure that includes a semiconductor substrate, a buried oxide layer formed on the semiconductor substrate and a top silicon layer formed on the buried oxide layer. The bipolar transistor structure includes: an opening formed in the top silicon layer; an opening in the buried oxide layer beneath the opening in the top silicon layer, the opening in the buried oxide layer including a region that undercuts the opening in the top silicon layer at a side of the opening in the top silicon layer; conductive material having a first conductivity type formed in the opening in the buried oxide layer such that the conductive material includes a region that undercuts the top silicon layer at the side of the opening in the top silicon layer; isolation dielectric material formed in the top silicon layer over the region of conductive material that undercuts the top silicon layer to define a bipolar transistor collector region having the first conductivity type, the collector region being in contact with the region of conductive material; a bipolar transistor base region formed in contact with an upper surface of the collector region, the base region having a second conductivity type that is opposite the first conductivity type; and an emitter region formed in contact with the base region, the emitter region having the first conductivity type.

### FIELD OF THE INVENTION

The present invention relates generally to bipolar transistors and, in particular, to integration of vertical bipolar junction transistors (BJT) or heterojunction bipolar transistors (HBT) into silicon-on-insulator (SOI) integrated circuit technology.

### BACKGROUND OF THE INVENTION

Silicon-on-insulator material used in advanced complimentary metal-oxide-silicon (CMOS) processes utilizes thin silicon layers on top of a buried oxide layer formed on semiconductor handle substrate material. The thin top silicon layer utilized in advanced CMOS technology presents a challenge with respect to integrating bipolar devices which require thicker silicon films.

### SUMMARY OF THE INVENTION

In an embodiment of the present invention, a bipolar transistor structure is formed on a silicon-on-insulator structure that includes a semiconductor substrate, a buried oxide layer formed on the semiconductor substrate and a top silicon layer formed on the buried oxide layer. The bipolar transistor structure includes: an opening formed in the top silicon layer; an opening in the buried oxide layer beneath the opening in the top silicon layer, the opening in the buried oxide layer including a region that undercuts the opening in the top silicon layer at a side of the opening in the top silicon layer; conductive material having a first conductivity type formed in the opening in the buried layer such that the conductive material includes a region that undercuts the top silicon layer at the side of the opening in the top silicon layer; isolation dielectric material formed in the top silicon layer over the region of conductive material that undercuts the top silicon layer to define a bipolar transistor collector region having the first conductivity type, the collector region being in contact with the region of conductive material; a bipolar transistor base region formed in contact with an upper surface of the collector region, the base region having a second conductivity type that is opposite the first conductivity type; and an emitter region formed in contact with the base region, the emitter region having the first conductivity type.

The features and advantages of the various aspects of the subject matter disclosed herein will be more fully understood and appreciated upon consideration of the following detailed description and the accompanying drawings, which set forth illustrative embodiments in which the concepts of the claimed subject matter are utilized.

### BRIEF DESCRIPTION OF THE DRAWINGS

FIGS. 1A-1I are cross section drawings illustrating a sequence of steps in an embodiment of a method for integrating a vertical BJT or HBT into SOI technology.

FIGS. 2A-2D are cross section drawings illustrating a sequence of steps in an alternate embodiment of a method for integrating a vertical BJT or HBT into SOI technology.

### DETAILED DESCRIPTION

Various illustrative embodiments of the invention are described below. In the interest of clarity, not all features of an actual implementation are described in this specification. It will of course be appreciated that in the development of any such actual implementation, numerous implementation specific decisions must be made to achieve the designer's specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached drawings. Various structures and methods are schematically depicted in the drawings for purposes of explanation only and so as not to obscure the present disclosure with details that are well known to those skilled in the art. Nevertheless, the attached drawings are included to describe illustrative embodiments of the present disclosure. The words and phrases utilized herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by those skilled in the art, such a special meaning will be expressly set forth in the specification in a definitional manner that directly and unequivocally provides the special definition for the term or phrase.

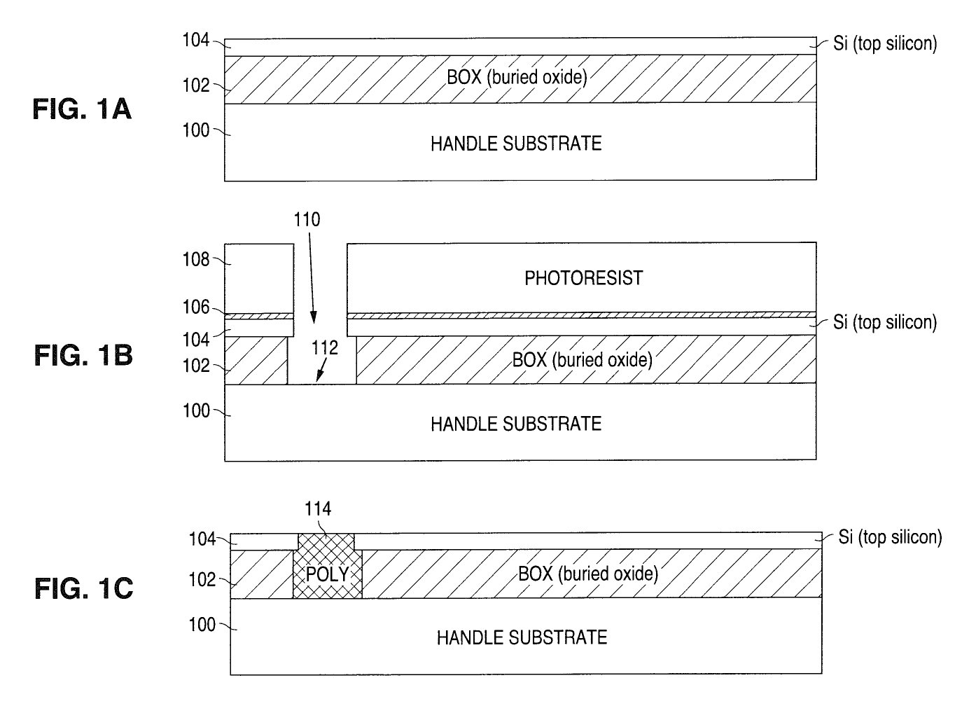

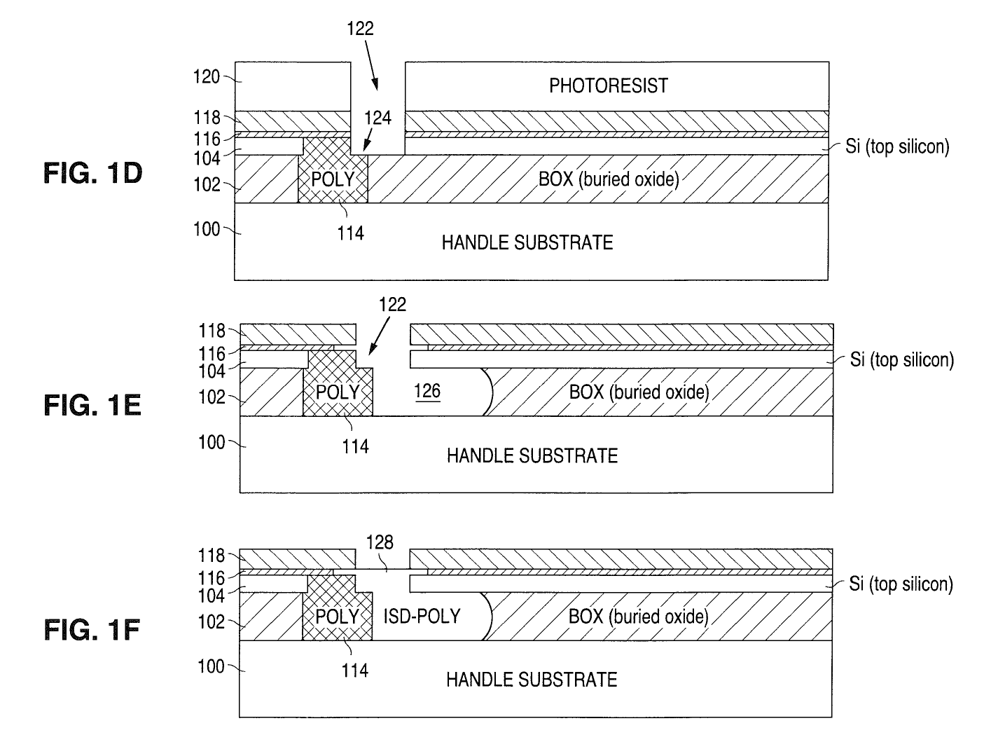

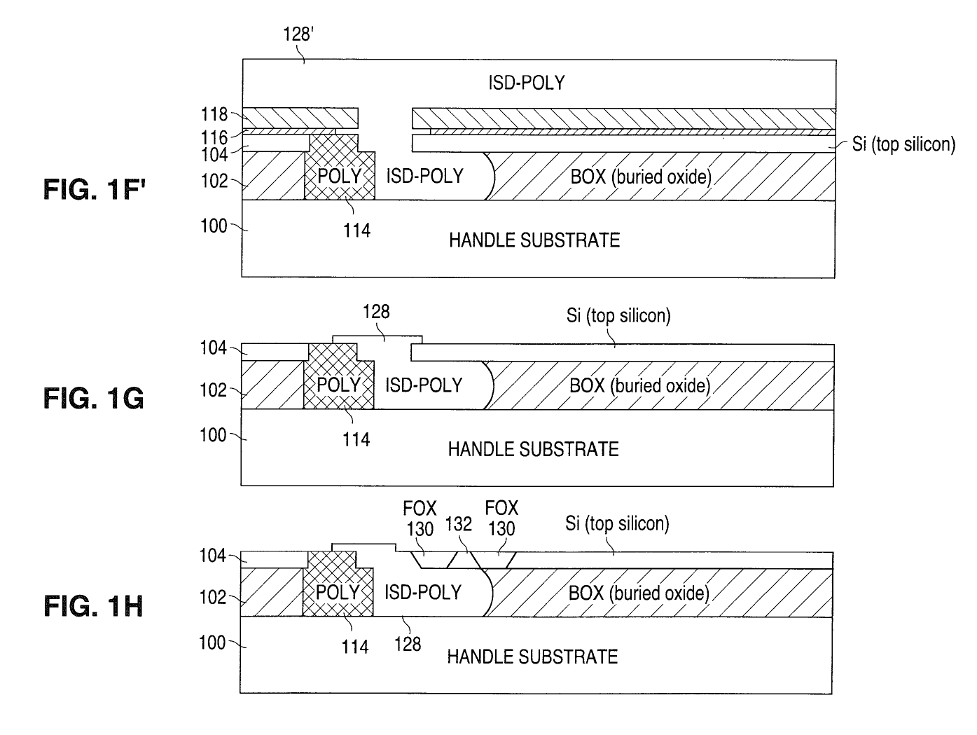

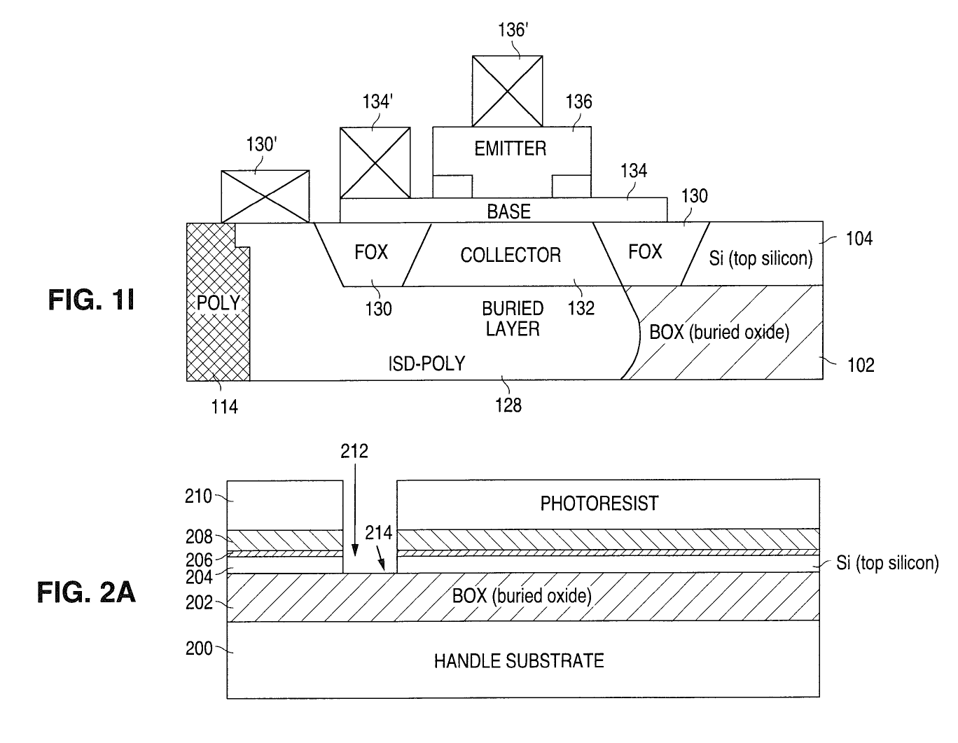

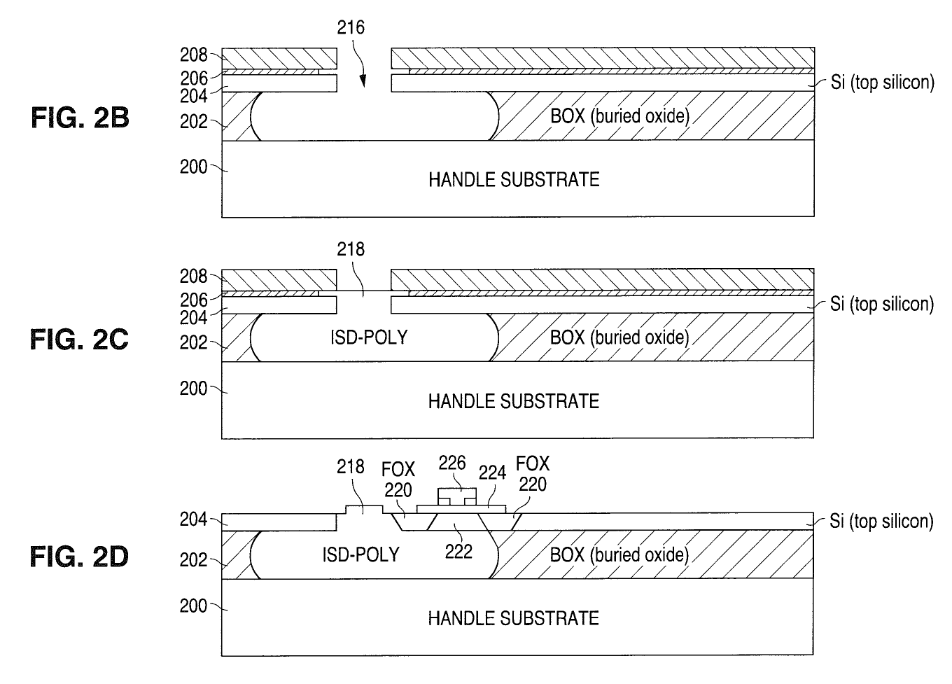

As stated above, generally, the present disclosure provides methods and structures for integrating vertical bipolar junction transistors (BJT) or heterojunction bipolar transistors (HBT) into silicon-on-insulator (SOI) technology. With reference to FIGS. 1A-1I and FIGS. 2A-2D, illustrative embodiments will now be described in detail.

FIGS. 1A-1I schematically illustrate an embodiment of the disclosed subject matter.

FIG. 1A shows silicon-on insulator (SOI) starting material that includes a semiconductor handle substrate 100, typically crystalline silicon. A buried oxide (BOX) layer 102, typically about 0.145-3.0 μm thick, is formed on the upper surface of the handle substrate 100. A relatively thin top silicon layer 104, typically about 20-90 nm thick, is formed on the upper surface of the buried oxide layer 102.

Next, as shown in FIG. 1B, a protection/planarization stop layer 106, e.g., silicon oxide, is grown or deposited on the upper surface of the top silicon layer 104. A patterned photoresist layer 108 is then utilized to etch through the protective/planarization stop layer 106, the top silicon layer 104 and the buried oxide layer 102 to form an opening 110 that exposes an area 112 of the upper surface of the handle substrate 100. The photoresist layer 108 is then stripped utilizing well known techniques.

The opening 110 is then filled with a “block” material 114 (e.g., polysilicon, amorphous silicon, or silicon nitride) to block future lateral removal of the buried oxide layer 102, as discussed in further detail below. The block material 114 is then planarized by etch back or chemical mechanical polishing (CMP) and the protective/planarization stop layer 106 is stripped using conventional techniques, resulting in the structure shown in FIG. 1C.

As shown in FIG. 1D, a thin silicon oxide protective/planarization stop layer 116 is then grown or deposited on the upper surface of the FIG. 1C structure. A silicon nitride layer 118 is formed on the oxide layer 116. A layer of patterned photoresist 120 is then formed on the nitride layer 118 and utilized to etch the nitride layer 118, the oxide layer 116 and the top silicon layer 106 to form an opening 122 in the top silicon layer 106 that overlaps the block material 114 and to expose a surface area 124 of the buried oxide layer 102.

As shown in FIG. 1E, the photoresist layer 120 is then stripped using well known techniques and a conventional wet etch step is performed to anisotropically etch the exposed buried oxide layer 102 to form an opening 126 that undercuts the top silicon layer 104 at one side of the opening 122 in the top silicon layer 104. The polysilicon block material 114 prevents the wet etch from etching the buried oxide layer 102 at the other side of the opening 122 in the top silicon layer 104. It is noted that the wet etch also results in the oxide layer 116 being undercut at both sides of the opening 122 in the top silicon layer 104.

The opening 126 in the buried oxide layer 102 is then filled with a conductive film (e.g., in-situ doped (ISD) polysilicon, ISD amorphous silicon, or ISD epitaxial grown crystalline silicon) to provide a buried collector/sinker region 128 having a first conductivity type (N-type or P-type). FIG. 1F shows the opening 126 having been filled by selective deposition of ISD polysilicon (or ISD amorphous silicon or ISD crystalline silicon); this method requires no further planarization. FIG. 1F′ shows the opening 126 having been filled using non-selective deposition of ISD polysilicon 128′ (or ISD amorphous silicon or ISD crystalline silicon); this method requires planarization of the deposited ISD polysilicon 128′ utilizing either etch back or CMP to arrive at the FIG. 1F buried collector/sinker region structure 128.

FIG. 1G shows that the nitride layer 118 and the oxide protective/planarization stop layer 116 are then stripped utilizing conventional techniques.

As shown in FIG. 1H, standard field oxide isolation (FOX) 130, for example shallow trench isolation (STI), is then formed in top silicon layer 104 over the buried collector/sinker region 128 to define a bipolar transistor collector region 132 in the top silicon layer 104 such that the collector region 132 is in contact with the buried collector/sinker region 128. Dopant having the first conductivity type is then introduced into the bipolar transistor collector region 132.

FIG. 1I shows the completion of the bipolar transistor structure, which may be either a vertical bipolar junction transistor (BIT) or heterojunction bipolar transistor (HBT). A bipolar transistor base region 134 having a second conductivity type (P-type or N-type) that is opposite the first conductivity type is formed in contact with an upper surface of the bipolar transistor collector region 132 in accordance with techniques well known to those skilled in the art. A bipolar transistor emitter region 136 having the first conductivity type is formed in contact with an upper surface of the bipolar transistor base region 134. FIG. 1H also shows a collector contact 130′, a base contact 134′ and an emitter contact 136′.

FIGS. 2A-2D schematically illustrate an alternate embodiment of the disclosed subject matter.

FIG. 2A shows a silicon-on-insulator (SOI) structure that includes a semiconductor handle substrate 200, typically crystalline silicon. A buried oxide (BOX) layer 202, typically about 0.145-3.0 μm thick, is formed on the upper surface of the handle substrate 200. A relatively thin top silicon layer 204, typically about 20-90 nm thick, is formed on the upper surface of the buried oxide layer 202.

As further shown in FIG. 2A, a thin silicon oxide protective/planarization layer 206 is deposited or grown on the upper surface of the top silicon layer 204. A silicon nitride layer 208 is formed on the oxide layer 206. A layer of patterned photoresist 210 is formed on the nitride layer 208 and utilized to etch the nitride layer 208, the oxide layer 206 and the top silicon layer 204 to form an opening 212 in the top silicon layer 204 that exposes a surface area 214 of the buried oxide layer 202.

As shown in FIG. 2B, the photoresist layer 210 is then stripped using well known techniques and a wet etch step is performed to anisotropically etch the buried oxide layer 202 to form an opening 216 that undercuts the top silicon layer 204 at both sides of the opening 212 in the top silicon layer 204. It is noted that the wet etch also results in the oxide layer 206 being undercut at both side of the opening 212 in the top silicon layer 204.

As shown in FIG. 2C, the opening 216 in the buried oxide layer 202 is then filled with a conductive film (e.g., ISD polysilicon, ISD amorphous silicon, ISD epitaxial grown crystalline silicon) to provide a buried collector/sinker region 218 having a first conductivity type (N-type or P-type). As discussed above in conjunction with FIGS. 1F and 1F′, the buried collector/sinker region 218 may be formed either by selective deposition of ISD polysilicon (or ISD amorphous silicon or ISD crystalline silicon), which requires no further planarization, or by-non-selective deposition of ISD polysilicon (or ISD amorphous silicon or ISD crystalline silicon) and subsequent planarization (etch back or CMP).

As shown in FIG. 2D, the nitride layer 208 and the oxide layer 206 are then stripped utilizing conventional techniques. Standard field oxide isolation (FOX) 220, for example shallow trench isolation (STI), is then formed in the top silicon layer 204 over the buried collector/sinker region 218 to define a bipolar transistor collector region 222 in the top silicon layer 204 such that the collector region 222 is in contact with the buried collector/sinker region 218. Dopant having the first conductivity type is then introduced into the collector region 222.

FIG. 2D also shows the completion of the bipolar transistor structure, which may be either a vertical bipolar junction transistor (BJT) or a heterojunction bipolar transistor (HBT). A bipolar transistor base region 224 having a second conductivity type (P-type or N-type) that is opposite the first conductivity type is formed in contact with an upper surface of the bipolar transistor collector region 222 in accordance with well known techniques. A bipolar transistor emitter region 226 having the first conductivity type is formed in contact with an upper surface of the bipolar transistor base region 224 in accordance with well known techniques.

It should be understood that the particular embodiments described herein have been provided by way of example and that other modifications may occur to those skilled in the art without departing from the scope of the claimed subject matter as expressed in the appended claims and their equivalents.

What is claimed is:

1. A method of forming a bipolar transistor on a silicon-on-insulator structure that includes a semiconductor substrate, a buried oxide layer formed on the semiconductor substrate and a top silicon layer formed on the buried oxide layer, the method comprising:
forming an opening in the top silicon layer to expose a surface area of the buried oxide layer;
utilizing the opening in the top silicon layer to etch the buried oxide layer beneath the exposed surface area of the buried oxide layer to form an opening in the buried oxide layer such that the opening in the buried oxide layer includes a first region that undercuts the opening in the top silicon layer on a first side of the opening in the top silicon layer;
filling the opening in the buried oxide layer with conductive material having a first conductivity type such that the conductive material includes a first region that undercuts the top silicon layer on the first side of the opening in the top silicon layer;
forming isolation dielectric material in the top silicon layer over the first region of conductive material that undercuts the top silicon layer to define a bipolar transistor collector region in the top silicon layer such that the collector region is in contact with the region of conductive material that undercuts the top silicon layer;
introducing dopant having the first conductivity type into the collector region;
forming a bipolar transistor base region in contact with an upper surface of the collector region, the base region having a second conductivity type that is opposite the first conductivity type; and
forming a bipolar transistor emitter region in contact with an upper surface of the base region, the emitter region having the first conductivity type.

2. The method of claim 1, wherein the semiconductor substrate comprises crystalline silicon.

3. The method of claim 1, wherein the conductive material is selected from the group consisting of in-situ doped (ISD) polysilicon, ISD amorphous silicon and ISD crystalline silicon.

4. The method of claim 1, wherein the step of filling the opening in the buried oxide layer comprises selectively depositing in-situ doped polysilicon to fill the opening in the buried oxide layer.

5. The method of claim 1, wherein the step of filling the opening in the buried oxide layer comprises non-selectively depositing in-situ doped polysilicon to fill the opening in the buried oxide layer and planarizing the deposited in situ doped polysilicon.

6. The method of claim 1, wherein the bipolar transistor comprises a vertical bipolar junction transistor (BJT).

7. The method of claim 1, wherein the bipolar transistor comprises a heterojunction bipolar transistor (HBT).

8. The method of claim 1, wherein the opening in the buried oxide layer includes a second region that undercuts the opening in the top silicon layer on a second side of the opening in the top silicon layer and the step of filling the opening in the buried oxide layer further comprises filling the second region with conductive material having the first conductivity type.

9. A bipolar transistor structure formed on a silicon-on-insulator structure that includes a semiconductor substrate, a buried oxide layer formed on the semiconductor substrate and a top silicon layer formed on the buried oxide layer, the bipolar transistor structure comprising:
an opening formed in the top silicon layer;
an opening in the buried oxide layer beneath the opening in the top silicon layer, the opening in the buried oxide layer including a region that undercuts the opening in the top silicon layer a first side of the opening in the top silicon layer;
conductive material having a first conductivity type formed in the opening in the buried oxide layer such that the conductive material includes a first region that undercuts the top silicon layer on the first one of the opening in the top silicon layer;
isolation dielectric material formed in the top silicon layer over the first region of conductive material that undercuts the top silicon layer to define a bipolar transistor collector region having the first conductivity type, the collector region being in contact with the first region of conductive material;
a bipolar transistor base region formed in contact with an upper surface of the collector region, the base region having a second conductivity type that is opposite the first conductivity type; and
an emitter region formed in contact with the base region, the emitter region having the first conductivity type.

10. The bipolar transistor structure of claim 8, wherein the conductive material is selected from the group consisting of in-situ doped (ISD) polysilicon, ISD amorphous silicon and ISD and ISD crystalline silicon.

11. The bipolar transistor structure of claim 8, wherein the bipolar transistor structure comprises a vertical bipolar junction transistor (BJT).

12. The bipolar transistor structure of claim 8, wherein the bipolar transistor structure comprises a heterojunction bipolar transistor (HBT).

13. The bipolar transistor structure of claim 8, wherein the opening in the buried oxide layer includes a second region that undercuts the opening in the top silicon layer on a second side of the opening in the top silicon layer and the second region of the opening in the buried oxide layer is filled with conductive material having the first conductivity type.

14. A method of forming a bipolar transistor on a silicon-on-insulator structure that includes a semiconductor substrate, a buried oxide layer formed on the semiconductor substrate and a top silicon layer formed on the buried oxide layer, the method comprising:
forming a first opening in the top silicon layer to expose a first surface area of the buried oxide layer;
utilizing the first opening in the top silicon layer to etch the buried oxide layer beneath the exposed first surface area of the buried oxide layer to form a first opening in the buried oxide layer;
filling the first opening in the buried oxide layer with block material;
forming a second opening in the top silicon layer to expose a second surface area of the buried oxide layer, the second opening in the top silicon layer overlapping the first opening in the top silicon layer at a first side of the second opening in the top silicon layer;
utilizing the second opening in the top silicon layer to etch the buried oxide layer beneath the exposed second surface of the buried oxide layer to form a second opening in the buried oxide layer such that the second opening in the buried oxide layer includes a region that undercuts the second opening in the top silicon layer on a second side of the opening in the top silicon layer;
filling the second opening in the buried oxide layer with conductive material having a first conductivity type such that the conductive material includes a region that undercuts the top silicon layer on the second side of the second opening in the top silicon layer;
forming isolation dielectric material in the top silicon layer over the region of conductive material that undercuts the top silicon layer to define a bipolar transistor collector region in the top silicon layer such that the collector region is in contact with the region of conductive material that undercuts the top silicon layer;
introducing dopant having the first conductivity type into the collector region;
forming a bipolar transistor base region in contact with an upper surface of the collector region, the base region having a second conductivity type that is opposite the first conductivity type; and
forming a bipolar transistor emitter region in contact with an upper surface of the base region, the emitter region having the first conductivity type.

15. The method of claim 13, wherein the block material is selected from the group consisting of polysilicon, amorphous silicon and crystalline silicon.

16. The method of claim 13, wherein the conductive material is selected from the group consisting of in-situ doped (ISD) polysilicon, ISD amorphous silicon and ISD crystalline silicon.

17. The method of claim 13, wherein the step of filling the second opening in the buried oxide layer comprises selectively depositing in-situ doped polysilicon to fill the second opening in the buried oxide layer.

18. The method of claim 13, wherein the step of filling the opening in the buried oxide layer comprises non-selectively depositing in-situ doped polysilicon to fill the opening in the buried oxide layer and planarizing the deposited in-situ doped polysilicon.

19. The method of claim 13, wherein the bipolar transistor is a vertical bipolar junction transistor (BJT).

20. The method of claim 13, wherein the bipolar transistor is a heterojunction bipolar transistor (HBT).

21. A bipolar transistor structure formed on a silicon-on-insulator structure that includes a semiconductor substrate, a buried oxide layer formed on the semiconductor substrate and a top silicon layer formed on the buried oxide layer, the bipolar transistor structure comprising:
an opening formed in the top silicon layer;
a region of block material formed in the buried oxide layer beneath a first surface region of the opening formed in the top silicon layer, the first surface region being located at a first side of the opening formed in the top silicon layer;
an opening in the buried oxide layer beneath a second surface region of the opening formed in the top silicon layer, the opening in the buried oxide layer including a region that undercuts the opening in the top silicon layer on a second side of the opening formed in the top silicon region;
conductive material having a first conductivity type formed in the opening in the buried oxide layer such that the conductive material includes a region that undercuts the top silicon layer on at the second side of the opening in the top silicon layer;
isolation dielectric material formed in the top silicon layer over the region of conductive material that that undercuts the top silicon layer to define a bipolar transistor collector region having the first conductivity type, the collector region being in contact with the region of conductive material;
a bipolar transistor base region formed in contact with an upper surface of the collector region, the base region having a second conductivity type that is opposite the first conductivity type; and
an emitter region formed in contact with the base region, the emitter region having the first conductivity type.

22. The bipolar transistor structure of claim 19, wherein the block material is selected form the group consisting of polysilicon, amorphous silicon and crystalline silicon.

23. The bipolar transistor structure of claim 19, wherein the conductive material is selected from the group consisting of in-situ doped (ISD) polysilicon, ISD amorphous silicon and ISD crystalline silicon.

24. The bipolar transistor structure of claim 19, wherein the bipolar transistor structure comprises a vertical bipolar junction transistor (BJT).

25. The bipolar transistor structure of claim 19, wherein the bipolar transistor structure comprises a heterojunction bipolar transistor.
